(19) United States
(12) Patent Application Publication
(10) Pub. No.: US 2022/0068703 A1
(43) Pub. Date: Mar. 3, 2022

(54) METAL INTERCONNECT WRAP AROUND WITH GRAPHENE

(71) Applicant: QUALCOMM Incorporated, San Diego, CA (US)

(72) Inventors: Junjing BAO, San Diego, CA (US); John Jianhong ZHU, San Diego, CA (US); Periannan CHIDAMBARAM, San Diego, CA (US)

(21) Appl. No.: 17/002,127

(22) Filed: Aug. 25, 2020

(51) Int. Cl. H01L 21/768; H01L 23/522; H01L 23/532

(52) U.S. Cl. CPC H01L 21/7685; H01L 21/76877; H01L 23/53204; H01L 23/5226

(57) ABSTRACT

Disclosed are examples of interconnect structures, e.g., in semiconductor packages. The interconnect structures may include metal lines with graphene. Graphene aids in reducing resistivity of metals used in interconnects. Graphene also serves as diffusion barriers. These properties are advantages when critical dimensions of conductive structures are reduced.

### FIELD OF DISCLOSURE

This disclosure relates generally to interconnect structures in semiconductor packages, and more specifically, but not exclusively, to interconnect structures that include metal interconnect wrap around with graphene and fabrication techniques thereof.

### BACKGROUND

Integrated circuit technology has achieved great strides in advancing computing power through miniaturization of active components. The package devices can be found in many electronic devices, including processors, servers, radio frequency (RF) integrated circuits, etc. Packaging technology becomes cost-effective in high pin count devices and/or high production volume components.

Due to surface scattering, electrical resistance of copper (Cu) scales very quickly when dimensions shrink. That is, when critical dimension (CD) shrinks such as the width of the metal, the resistance increases quickly. Since the industry is moving to smaller and smaller dimensions (e.g., 12 nm and below), the increase in the resistance can lead to a greater resistance-capacitance (RC) delay.

Accordingly, there is a need for systems, apparatus, and methods that overcome the deficiencies of conventional interconnect structure packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary interconnect structure is disclosed. The interconnect structure may comprise a lower line formed in a dielectric. The interconnect structure may also comprise an upper line formed on or above the lower line. The upper line may be electrically coupled with the lower line. The upper line may comprise an upper metal formed on or above the lower line. The upper line may also comprise an upper graphene formed on at least a portion of an upper surface of the upper metal, at least a portion of a first side surface of the upper metal, and/or at least a portion of a second side surface of the upper metal.

A method of fabricating an exemplary interconnect is disclosed. The method may comprise forming a lower line in a dielectric. The method may also comprise forming an upper line on or above the lower line. The upper line may be electrically coupled with the lower line. The upper line may comprise an upper metal formed on or above the lower line. The upper line may also comprise an upper graphene formed on at least a portion of an upper surface of the upper metal, at least a portion of a first side surface of the upper metal, and/or at least a portion of a second side surface of the upper metal.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates an example of a conventional interconnect structure.

FIGS. 2A-2B illustrate examples of interconnect structure in accordance with at one or more aspects of the disclosure.

FIGS. 3A-3E and 4A-4D illustrate examples stages of fabricating interconnect structures in accordance with at one or more aspects of the disclosure.

FIGS. 5-7 illustrate flow charts of an example method of manufacturing an interconnect structure in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

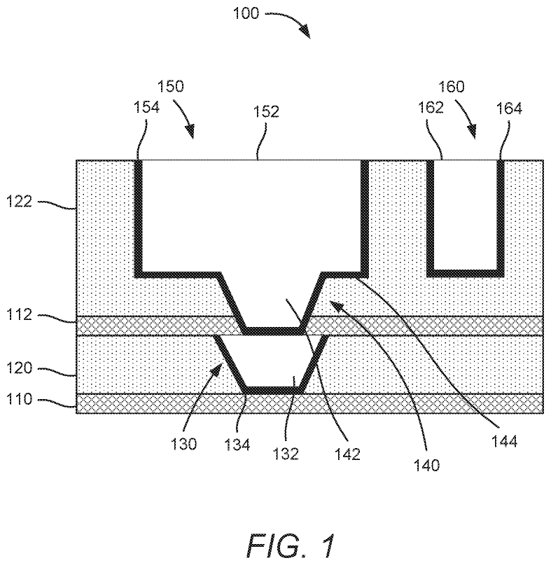

FIG. 1 illustrates an example of a conventional interconnect structure 100 comprising a first etch stop 110, a first dielectric 120 on the first etch stop 110, a lower line 132 within the first dielectric 120, a second etch stop 112 on the first dielectric 120, a second dielectric 122 on the second etch stop 112, a via 140 on the lower line 130, an upper line 150 on the via 140, and an adjacent line 160. The via 140, the upper line 150, and the adjacent line 160 are within the second dielectric 122.

The lower line 130, the via 140, the upper line 150 and the adjacent line 160 are all electrically conductive. The upper line 150 and the lower line 130 are electrically coupled with each other through the via 140. The adjacent line 160 is electrically decoupled from the upper line 150, the via 140, and the lower line 130. The lower line 130 comprises a lower tantalum nitride (TaN) 134 and a lower Cu 132, the via 140 comprises a via TaN 144 and a via Cu 142, the upper line 150 comprises an upper TaN 154 and an upper Cu 152, and the adjacent line 160 comprises an adjacent TaN 164 and an adjacent Cu 162.

As indicated above, decrease in the critical dimension (CD) of interconnects can lead to an increase in resistivity due to unscaled barrier/liner thickness and electron scattering. For example, as the widths of the lower line 130 and/or the via 140 (e.g., the widths of the lower Cu 132 and/or the via Cu 142) decrease, the resistance of the interconnect structure 100 increases. This in turn can lead to undesirable RC delay increase.

In accordance with the various aspects disclosed herein, to address issues associated with conventional interconnect structures, it is proposed to encapsulate metal interconnects with graphene. One advantage is that the resistivity of a metal with graphene encapsulation is lower than the resistivity of the metal without graphene encapsulation. As a result, RC delay may be decreased with the use of graphene. Another advantage is that graphene is a very good diffusion barrier. This means that during fabrication, distance between adjacent conductive lines can be shortened without the concern of having unintended shorts due to diffusion of conductive materials.

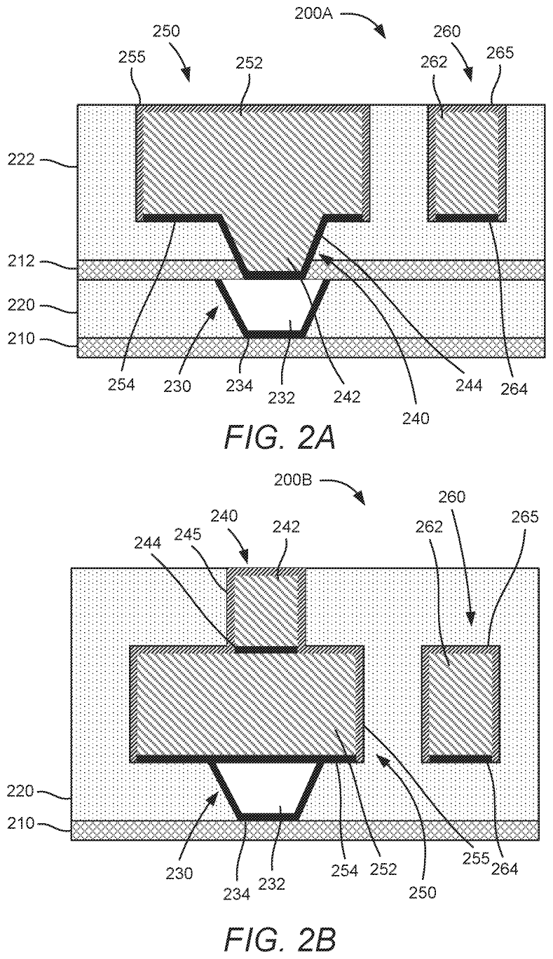

FIGS. 2A, 2B illustrate example interconnect structures 200A, 200B in accordance with at one or more aspects of the disclosure. Each of the interconnect structures 200A, 200B may include a lower line 230, a via 240, an upper line 250, and an adjacent line 260, all of which may be conductive. The lower line 230, the via 240, and the upper line 250 may be electrically coupled together. The adjacent line 260, which may be horizontally adjacent to the upper line 250, may be electrically decoupled from the lower line 230, the via 240, and the upper line 250. The lower line 230 may be formed in a dielectric (first dielectric 220 in FIG. 2A, dielectric 220 in FIG. 2B). The via 240, the upper line 250, and the adjacent line 260 may be formed in a different dielectric (second dielectric 222 in FIG. 2A) or in a same dielectric (dielectric 220 in FIG. 2B).

The lower line 230 may comprise a barrier layer 234 formed on the dielectric 220 and a lower conductor 232 on the barrier layer 234. In this context, “on” may be synonymous with “in contact with”. Note that the barrier layer 234 may be optional, i.e., the lower line 230 may comprise the lower conductor 232 without the barrier layer 234. In this instance, the lower conductor 232 may be formed on the dielectric 220. In an aspect, upper surfaces of the lower conductor 232 and the dielectric 220 may be substantially planar.

The via 240 may comprise a via metal 242 and a via adhesion layer 244 (optional). The upper line 250 may comprise an upper metal 252 and an upper adhesion layer 254 (optional). The adjacent line 260 may comprise an adjacent metal 262 and an adjacent adhesion layer 264 (optional). The via metal 242, the upper metal 252, and/or the adjacent metal 262 may each comprise any combination of Rhodium (Rh), Platinum (Pt), Iridium (Ir), Niobium (Nb), Nickel (Ni), Aluminium (Al), Ruthenium (Ru), Molybdenum (Mo), Osmium (Os), Copper (Cu), Cobalt (Co), etc. Generally, one or more combinations of transition metals and/or post-transitions metals may be used. The via adhesion layer 244, the upper adhesion layer 254, and/or the adjacent adhesion layer 264 may each comprise TiN, TaN, WN, RuN, etc.

The upper line 250 may also comprise an upper graphene 255 on one or more surfaces of the upper metal 252. For example, the upper graphene 255 may be formed on at least a portion of an upper surface of the upper metal 252, on at least a portion of a first side surface (e.g., left surface) of the upper metal 252, and/or on at least a portion of a second side surface (e.g., right surface) of the upper metal 252. If present, the upper graphene 255 may also be formed on first and/or second side surfaces of the upper adhesion layer 254. Generally, the upper graphene 255 may be formed to encapsulate the upper metal 252 as much as possible to maximize reduction in the resistivity of the upper line 250.

The adjacent line 260 may also comprise an adjacent graphene 265 on one or more surfaces of the adjacent metal 262. For example, the adjacent graphene 265 may be formed on at least a portion of an upper surface of the adjacent metal 262, on at least a portion of a first side surface (e.g., left surface) of the adjacent metal 262, and/or on at least a portion of a second side surface (e.g., right surface) of the adjacent metal 262. If present, the adjacent graphene 265 may also be formed on first and/or second side surfaces of the adjacent adhesion layer 264. Generally, the adjacent graphene 265 may be formed to encapsulate the adjacent metal 265 as much as possible to maximize reduction in the resistivity of the adjacent line 260. For example, the adjacent graphene 265 may be formed on an entirety of the upper surface of the adjacent metal 262, on an entirety of the first side surface of the adjacent metal 262, and/or on an entirety of the second side surface of the adjacent metal 262 as seen in FIGS. 2A and 2B.

The upper metal 252 and the adjacent metal 262 may be formed from a same metal or a same combination of metals. For example, both metals may be formed from a same deposition process (details provided further below).

The via 240 and the upper line 250 of both interconnect structures 200A, 200B are illustrated as being above the lower line 230 in FIGS. 2A, 2B. It should be noted that terms or phrases such as “lower”, “upper”, “left”, “right”, “below”, “above”, “horizontal, “vertical”, etc. are used for convenience. Unless otherwise specifically indicated, such terms/phrased are not intended to indicate absolute orientations or directions. Also as indicated, terms “on” and “in contact with” may be used synonymously unless otherwise specifically indicated.

A difference between the interconnect structures 200A, 200B is in the relative positioning of the via 240 and the upper line 250. In the interconnect structure 200A (FIG. 2A), the via 240 is illustrated as being formed on an upper surface of the lower line 230 and on a lower surface of the upper line 250, i.e., in between the upper line 250 and the lower line 230. As such, the upper line 250 may be electrically coupled with the lower line 230 through the via 240 in the interconnect structure 200A. The upper metal 252 and the via metal 242 may be formed from a same metal or a same combination of metals. Indeed, they may be integrally formed, e.g., formed as a single element.

As indicated, it may be preferable to encapsulate or otherwise cover the upper metal 252 with the upper graphene 255 as much as possible. Then in an aspect with regard to the interconnect structure 200A, the upper graphene 255 may be formed on an entirety of the upper surface of the upper metal 252, on an entirety of the first side surface of the upper metal 252, and/or on an entirety of the second side surface of the upper metal 252.

In the interconnect structure 200B (FIG. 2B), the via 240 may be formed on the upper surface of the upper metal 252 of the upper line 250. The upper line 250 itself may be formed on the upper surface of the lower line 230. As such, the via 240 may be electrically coupled with the lower line 230 through the upper line 250 in the interconnect structure 200B. The upper metal 252 and the via metal 242 may be formed from a same metal or a same combination of metals.

In an aspect with regard to the interconnect structure 200B, to minimize resistivity (or maximize reduction in resistivity), the upper graphene 255 may be formed on an entirety of the upper surface of the upper metal 252 not covered by the via 240, on an entirety of the first side surface of the upper metal 252, and/or on an entirety of the second side surface of the upper metal 252.

In the interconnect structure 200B, the via 240 may also include a via graphene 245 formed on at least a portion of an upper surface of the via metal 242, on at least a portion of a first side surface (e.g., left surface) of the via metal 242, and/or on at least a portion of a second side surface (e.g., right surface) of the via metal 242. Again, to minimize resistivity (or maximize reduction in resistivity), the via graphene 245 may formed on an entirety of the upper surface of the via metal 242, on an entirety of the first side surface of the via metal 242, and/or on an entirety of the second side surface of the via metal 242. In an aspect, the upper graphene 255 and the via graphene 245 may be integrally formed.

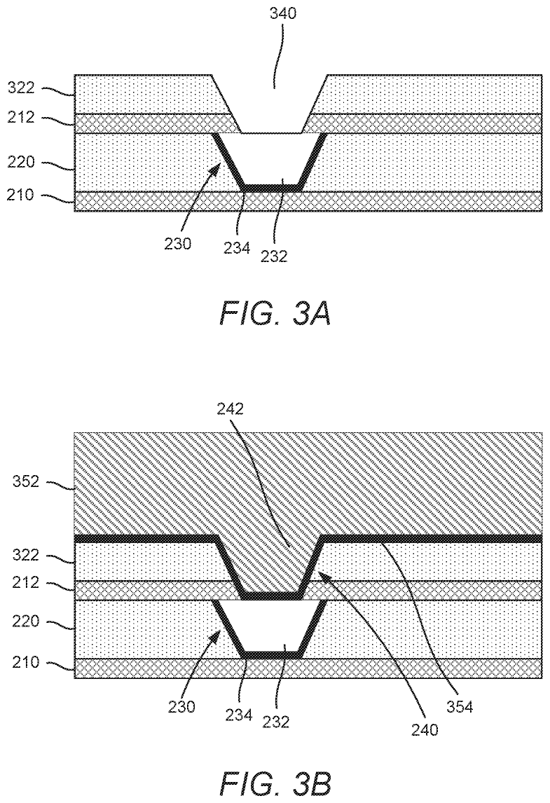

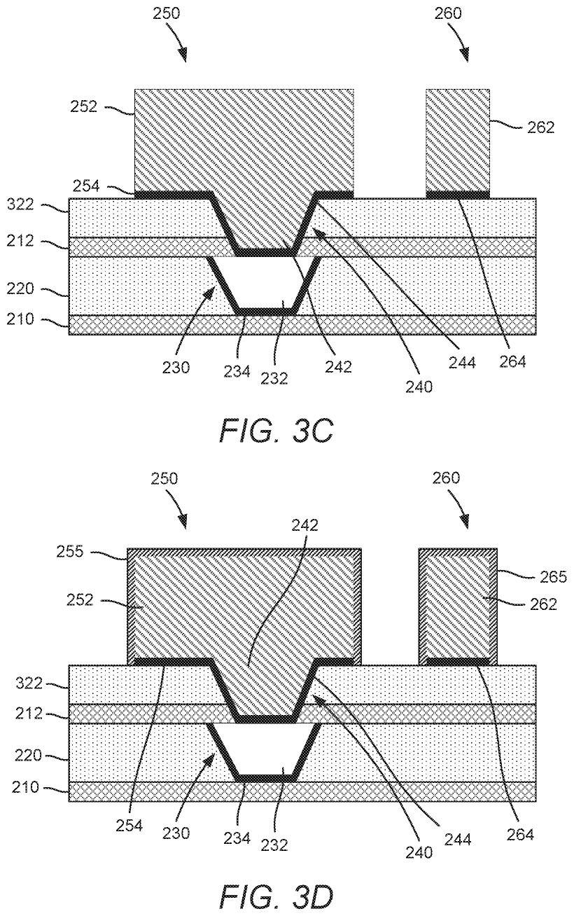

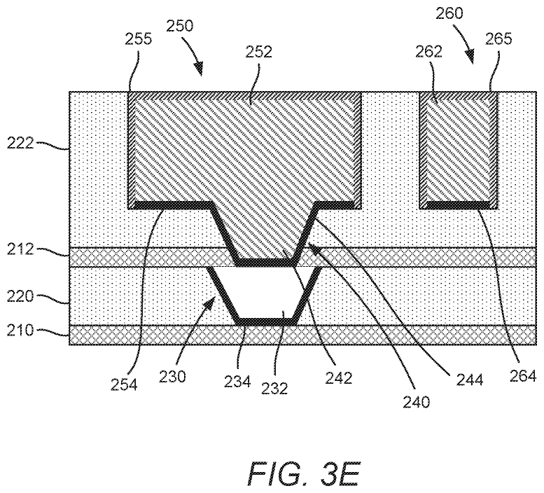

FIGS. 3A-3E illustrate example stages of fabricating an interconnect structure, such as the interconnect structure 200A, in accordance with one or more aspects of the disclosure.

FIG. 3A illustrates a stage in which a via pattern 340 may be etched to expose at least a portion of the upper surface of the lower line 230, which may be formed within the first dielectric 220. In particular, the second etch stop 212 (e.g., silicon carbon nitride (SiCN), aluminum nitride/oxygen doped carbon (AlN/ODC), etc.) and the second dielectric 222 may be damascene etched.

FIG. 3B illustrates a stage in which an adhesion layer 354 (e.g., TiN, TaN, WN, RuN, etc.) may be deposited on the second dielectric 222 including the portion exposed within the via pattern 340, the exposed portion of the etch stop layer 212 within the via pattern 340, and the exposed portion of the upper surface of the lower line 230. Thereafter, a metal layer 352 (e.g., Rh, Pt, Ir, Nb, Ni, Al, Ru, Mo, Os, Cu, Co, etc.) may be deposited on the adhesion layer 354 to fill the via pattern 340. Filling the via pattern 340 with the metal layer 352 may effectively form the via 240.

Note that the adhesion layer 354 may be optional. If the adhesion layer 354 is not provided, then the metal layer 352 may be deposited directly on the on the second dielectric 222 including the portion exposed within the via pattern 340, the exposed portion of the etch stop layer 212 within the via pattern 340, and the exposed portion of the upper surface of the lower line 230 to fill the via pattern 340. Again, the via 240 may effectively be formed when the via pattern 340 is filled with the metal layer 352.

Then FIG. 3B may be said to illustrate a stage in which the metal layer 352 may be deposited on or above the second dielectric layer 322 and on or above the lower line 230. The metal layer 352 may fill the via pattern 340 to form the via 240.

FIG. 3C illustrates a stage in which the metal layer 352 may be etched to form the upper metal 252 and the adjacent metal 262. If the adhesion layer 354 is present, then the process of etching the metal layer 352 may also etch the adhesion layer 354 to form the upper adhesion layer 254 and the adjacent adhesion layer 264. Note that the via metal 242, the upper metal 252 and the adjacent metal 262 may all be of same metal or combination of metals since they are all from the same metal layer 352. Indeed, the via metal 242 and the upper metal 252 may be integrally formed.

FIG. 3D illustrates a stage in which upper graphene 255 and the adjacent graphene 265 may be formed. In an aspect, a same low temperature chemical vapor deposition (CVD) process may be used to grow the upper graphene 255 and the adjacent graphene 265 contemporaneously. For example, they may be grown simultaneously.

The upper graphene 255 may be grown on at least a portion of the upper surface of the upper metal 252, on at least a portion of the first side surface of the upper metal 252, and/or on at least a portion of the second side surface of the upper metal 252. Preferably, the upper graphene 255 may be grown on entireties of upper, first side, and/or second side surfaces of the upper metal 252.

Similarly, the adjacent graphene 265 may be grown on at least a portion of the upper surface of the adjacent metal 262, on at least a portion of the first side surface of the adjacent metal 262, and/or on at least a portion of the second side surface of the adjacent metal 262. Preferably, the adjacent graphene 265 may be grown on entireties of upper, first side, and/or second side surfaces of the adjacent metal 262.

FIG. 3E illustrates a stage in which the second dielectric 222 is completed to surround the via 240, the upper line 250, and the adjacent line 260. In an aspect, a low-k dielectric film (e.g., SiOC, SiCOH, SiO, etc.) may be used for fill in reflow.

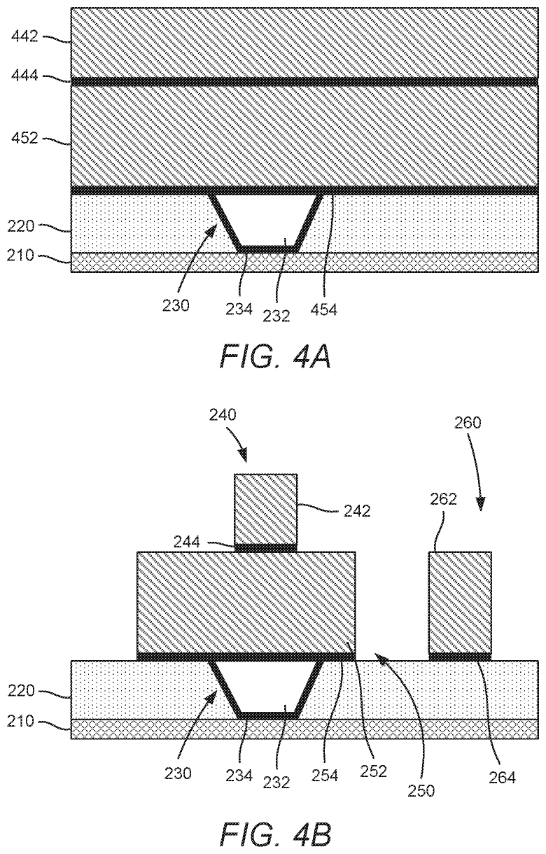

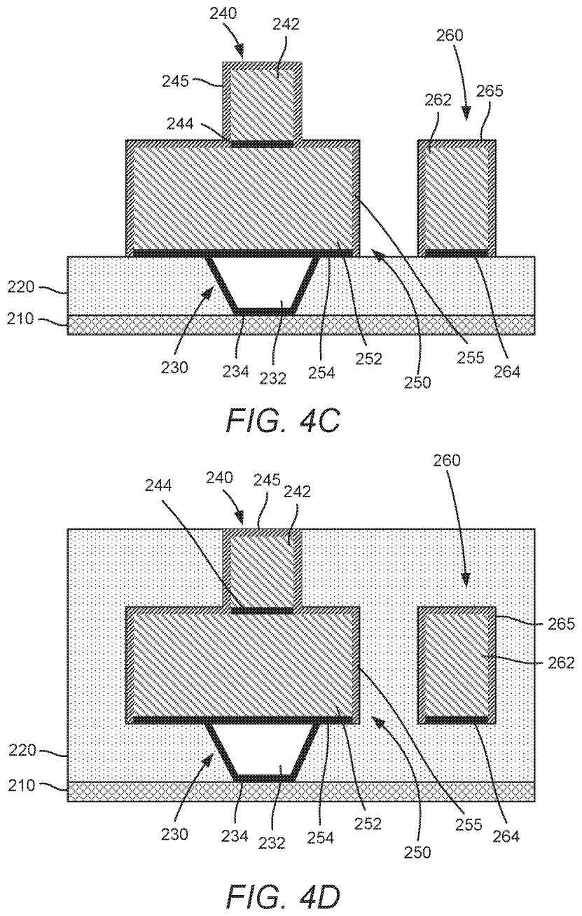

FIGS. 4A-4D illustrate example stages of fabricating an interconnect structure, such as the interconnect structure 200B, in accordance with one or more aspects of the disclosure.

FIG. 4A illustrates a stage in which a first adhesion layer 454 (e.g., TiN, TaN, WN, RuN, etc.), which may be optional, may be deposited on the dielectric 220 and on the lower line 230. Thereafter, a first metal layer 452 (e.g., Rh, Pt, Ir, Nb, Ni, Al, Ru, Mo, Os, Cu, Co, etc.) may be deposited on the first adhesion layer 454. When the first adhesion layer 454 is not present, it may be said that the first metal layer 452 may be deposited on the dielectric 220 and on the lower line 230. When the first adhesion layer 454 is present, it may be said that the first metal layer 452 may be deposited over the dielectric 220 and over the lower line 230.

FIG. 4A also illustrates that a second adhesion layer 444 (e.g., TiN, TaN, WN, RuN, etc.), which may be optional, may be deposited on an upper surface of the first metal layer 452. Thereafter, a second metal layer 442 (e.g., Rh, Pt, Ir, Nb, Ni, Al, Ru, Mo, Os, Cu, Co, etc.) may be deposited on the second adhesion layer 444. When the second adhesion layer 444 is not present, it may be said that the second metal layer 442 may be deposited on the first metal layer 452. When the second adhesion layer 444 is present, it may be said that the second metal layer 442 may be deposited over the first metal layer 452. The first metal layer 452 and the second metal layer 442 may be same or different.

FIG. 4B illustrates a stage in which the first metal layer 452 and the second metal layer 442 may be etched to form the upper metal 252 and the via metal 242 above the upper metal 252. The adjacent metal 262 may also be formed when the first metal layer 452 is etched. If the first adhesion layer 454 is present, then the process of etching the first metal layer 452 may also etch the first adhesion layer 454 to form the upper adhesion layer 254 and the adjacent adhesion layer 264. If the second adhesion layer 444 is present, then the process of etching the second metal layer 442 may also etch the second adhesion layer 444 to form the via adhesion layer 244. Note that the upper metal 252 and the adjacent metal 262 may be of same metal or combination of metals since they are all from the same first metal layer 452. The via metal 242 may be of the same or different metal or combination of metals depending on whether or not the first metal layer 452 and the second metal layer 442 are same or different.

FIG. 4C illustrates a stage in which the upper graphene 255, the adjacent graphene 265 and the via graphene 245 may be formed. In an aspect, a same low temperature chemical vapor deposition (CVD) process may be used to grow the upper graphene 255, the adjacent graphene 265 and the via graphene 245 contemporaneously. For example, they may be grown simultaneously.

The upper graphene 255 may be grown on at least a portion of the upper surface of the upper metal 252, on at least a portion of the first side surface of the upper metal 252, and/or on at least a portion of the second side surface of the upper metal 252. Preferably, the upper graphene 255 may be grown on an entirety of the upper surface of the upper metal 252 not covered by the via 240, an entirety of the first side surface of the upper metal 252, and/or an entirety of the second side surface of the upper metal 252.

The adjacent graphene 265 may be grown on at least a portion of the upper surface of the adjacent metal 262, on at least a portion of the first side surface of the adjacent metal 262, and/or on at least a portion of the second side surface of the adjacent metal 262. Preferably, the adjacent graphene 265 may be grown on entireties of upper, first side, and/or second side surfaces of the adjacent metal 262.

The via graphene 245 may be grown on at least a portion of the upper surface of the via metal 242, on at least a portion of the first side surface of the via metal 242, and/or on at least a portion of the second side surface of the via metal 242. Preferably, the via graphene 245 may be grown on entireties of upper, first side, and/or second side surfaces of the adjacent metal 262.

FIG. 4D illustrates a stage in which the second dielectric 222 is completed to surround the via 240, the upper line 250, and the adjacent line 260. In an aspect, a low-k dielectric film (e.g., SiOC, SiCOH, SiO, etc.) may be used for fill in reflow.

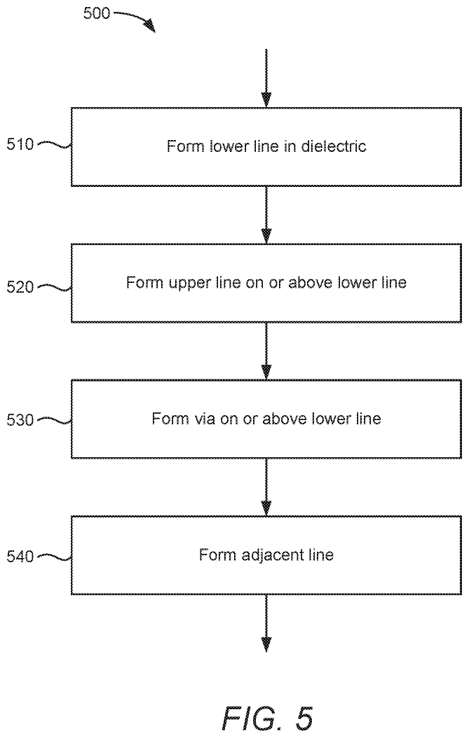

FIG. 5 illustrates a flow chart of an example method 500 fabricating an interconnect structure, such as interconnect structures 200A, 200B, in accordance with at one or more aspects of the disclosure.

In block 510, a lower line 230 may be formed in a dielectric 220. For example, in both FIGS. 2A and 2B, the lower line 230 is illustrated as being formed in the dielectric 220.

In block 520, an upper line 250 may be on or above the lower line 230. In both FIGS. 2A and 2B, the upper line 250 is illustrated as being formed above the lower line 230. But in FIG. 2B, the upper line 250 may also be described as being on the lower line 230. In both interconnect structures 200A and 200B, the upper line 250 may be electrically coupled with the lower line 230.

In block 530, a via 240 may be formed on or above the lower line 230. In both FIGS. 2A and 2B, the via 240 is illustrated as being formed above the lower line 230. But in FIG. 2A, the via 240 may also be described as being on the lower line 230. In both interconnect structures 200A and 200B, the via 240 may be electrically coupled with the lower line 230 and with the upper line 250.

In block 540, an adjacent line 260, which may be horizontally adjacent to the upper line 250, may be formed above the lower line 230.

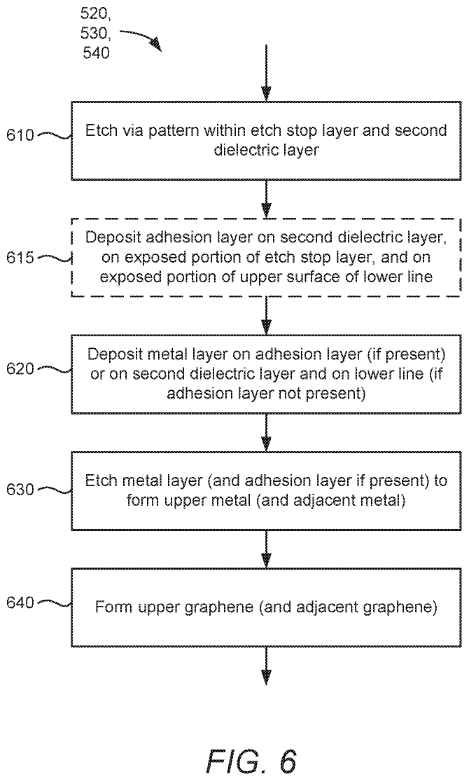

FIG. 6 illustrates a flow chart of an example process to implement blocks 520, 530, 540. The flow chart of FIG. 6 may be implemented to fabricate the interconnect structure 200A of FIG. 2A.

In block 610, the via pattern 340 may be etched within an etch stop layer 212 and the second dielectric layer 322. The etch stop layer 212 may be formed on the first dielectric 220 and on the lower line 230, and the second dielectric layer 322 may be formed on the etch stop layer 212. The via pattern 340 may expose at least a portion of an upper surface of the lower line 230. A damascene process may be used to etch the etch stop layer 212 and the second dielectric layer 322 to form the via pattern 340. FIG. 3A may represent block 610.

Optionally in block 615, the adhesion layer 354 may be deposited on the second dielectric layer 322, on exposed portion of the etch stop layer 212, and on the exposed portion of the upper surface of the lower line 230. FIG. 3B may represent block 615.

In block 620, the metal layer 352 may be deposited on or above the second dielectric layer 322 and on or above the lower line 230. The metal layer 352 may fill the via pattern 340 to form the via 240. FIG. 3B may also represent block 620.

In block 630, the metal layer 352 may be etched to form the upper metal 252. If present, the adhesion layer 354 may also be etched to form the upper adhesion layer 254. The metal layer 352 (and the adhesion layer 354 if present) may be etched to form the adjacent metal 262 (and the adjacent adhesion layer 264) contemporaneously. FIG. 3C may represent block 630.

In block 640, the upper graphene 255 may be formed on the upper, the first side, and/or the second side surfaces of the upper metal 252. For example, a low temperature CVD process may be used to grow the upper graphene 255. The same process may also be used to contemporaneously form the adjacent graphene 265 on the upper, the first side, and/or the second side surfaces of the adjacent metal 262. FIG. 3D may represent block 640. Thereafter, as illustrated in FIG. 3E, the second dielectric 222 may be filled.

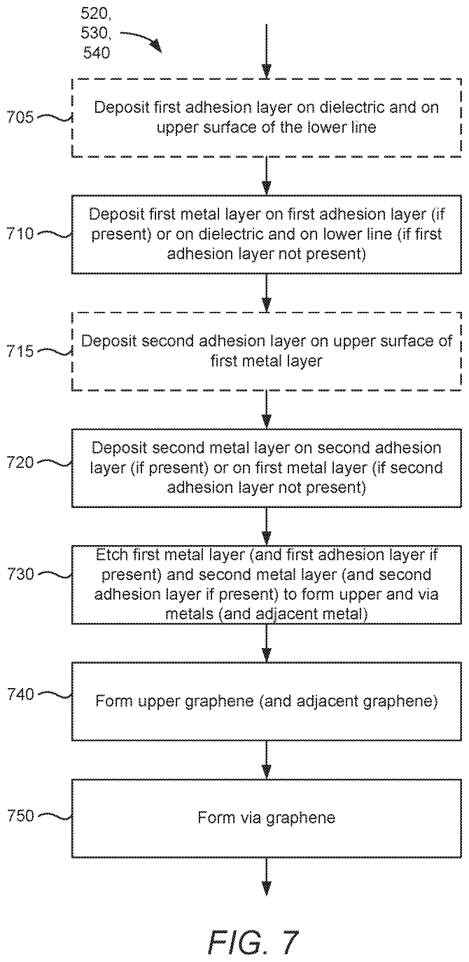

FIG. 7 illustrates a flow chart of another example process to implement blocks 520, 530, 540. The flow chart of FIG. 7 may be implemented to fabricate the interconnect structure 200B of FIG. 2B.

Optionally in block 705, the upper adhesion layer 354 may be deposited on the dielectric 220 and on the upper surface of the lower line 230. FIG. 4A may represent block 705.

In block 710, the first metal layer 452 may be deposited on or above the dielectric 220 and on or above the lower line 230. FIG. 4A may also represent block 710.

Optionally in block 715, the second adhesion layer 444 may be deposited on an upper surface of the first metal layer 452. FIG. 4A may further represent block 715.

In block 720, the second metal layer 442 may be deposited on or above the first metal layer 452. FIG. 4A may further represent block 720.

In block 730, the first metal layer 452 and the second metal layer 442 may be etched to form the upper metal 252 and to form the via metal 242 above the upper metal 252. If present, the first adhesion layer 454 may be etched to form the upper adhesion layer 254 when the first metal layer 452 is etched. If present, the second adhesion layer 444 may be etched to form the via adhesion layer 244 when the second metal layer 442 is etched. The first metal layer 452 (and the first adhesion layer 454 if present) may be etched to form the adjacent metal 262 (and the adjacent adhesion layer 264) contemporaneously. FIG. 4B may represent block 730.

In block 740, the upper graphene 255 may be formed on the upper, the first side, and/or the second side surfaces of the upper metal 252. For example, a low temperature CVD process may be used to grow the upper graphene 255. The same process may also be used to contemporaneously form the adjacent graphene 265 on the upper, the first side, and/or the second side surfaces of the adjacent metal 262. FIG. 4C may represent block 740.

In block 750, the via graphene 245 may be formed on the upper, the first side, and/or the second side surfaces of the via metal 242. The same low temperature CVD process used to grow the upper and adjacent graphenes 255, 265 may be used to contemporaneously grow the via graphene 245. FIG. 4C may also represent block 750. Thereafter, as illustrated in FIG. 4D, the dielectric 22—may be filled.

It will be appreciated that the foregoing fabrication processes and related discussion were provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations. Further, it will be appreciated that the illustrated configurations and descriptions are provided merely to aid in the explanation of the various aspects disclosed herein.

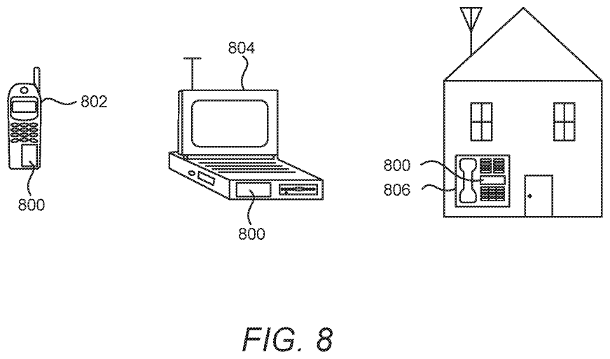

FIG. 8 illustrates various electronic devices that may be integrated with any of the aforementioned interconnect structures 200A, 200B in accordance with various aspects of the disclosure. For example, a mobile phone device 802, a laptop computer device 804, and a fixed location terminal device 806 may each be considered generally user equipment (UE) and may include the interconnect structures 200A, 200B as described herein. The devices 802, 804, 806 illustrated in FIG. 8 are merely exemplary. Other electronic devices may also include the interconnect structures including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

The following provides an overview of examples of the present disclosure:

### Example 1

An interconnect structure, comprising: a lower line formed in a dielectric; and an upper line formed on or above the lower line, the upper line being electrically coupled with the lower line, the upper line comprising: an upper metal formed on or above the lower line; and an upper graphene formed on at least a portion of an upper surface of the upper metal, at least a portion of a first side surface of the upper metal, and/or at least a portion of a second side surface of the upper metal.

### Example 2

The interconnect structure of example 1, wherein the upper metal comprises any one or more of Rhodium (Rh), Platinum (Pt), Iridium (Ir), Niobium (Nb), Nickel (Ni), Aluminium (Al), Ruthenium (Ru), Molybdenum (Mo), Osmium (Os), Copper (Cu), and Cobalt (Co).

### Example 3

The interconnect structure of any of examples 1-2, wherein the upper line further comprises: an upper adhesion layer formed on a lower surface of the upper metal.

### Example 4

The interconnect structure of any of examples 1-3, further comprising: a via formed on or above the lower line, the via being electrically coupled with the upper line and with the lower line, the via comprising a via metal.

### Example 5

The interconnect structure of example 4, wherein the via metal is formed from same metal or metals as the upper metal.

### Example 6

The interconnect structure of any of examples 4-5, wherein the via further comprises: a via adhesion layer formed on a lower surface of the via metal

### Example 7

The interconnect structure of any of examples 4-6, wherein the via is formed on an upper surface of the lower line and on a lower surface of the upper line such that the upper line is electrically coupled with the lower line through the via.

### Example 8

The interconnect structure of example 7, wherein the via metal and the upper metal are integrally formed.

### Example 9

The interconnect structure of any of examples 7-8, wherein the upper graphene is formed on an entirety of the upper surface of the upper metal, an entirety of the first side surface of the upper metal, and/or an entirety of the second side surface of the upper metal.

### Example 10

The interconnect structure of any of examples 4-6, wherein the via is formed on an upper surface of the upper metal such that the via is electrically coupled with the lower line through the upper metal.

### Example 11

The interconnect structure of example 10, wherein the upper graphene is formed on an entirety of the upper surface of the upper metal not covered by the via, an entirety of the first side surface of the upper metal, and/or an entirety of the second side surface of the upper metal.

### Example 12

The interconnect structure of any of examples 10-11, wherein the via further comprises a via graphene formed on at least a portion of an upper surface of the via metal, at least a portion of a first side surface of the via metal, and/or at least a portion of a second side surface of the via metal.

### Example 13

The interconnect structure of example 12, wherein the via graphene is formed on an entirety of the upper surface of the via metal, an entirety of the first side surface of the via metal, and/or an entirety of the second side surface of the via metal.

### Example 14

The interconnect structure of any of exampled 12-13, wherein the via graphene and the upper graphene are integrally formed.

### Example 15

The interconnect structure of any of examples 1-14, further comprising: an adjacent line horizontally adjacent to the upper line, the adjacent line comprising: an adjacent metal; and an adjacent graphene formed on at least a portion of an upper surface of the adjacent metal, at least a portion of a first side surface of the adjacent metal, and/or at least a portion of a second side surface of the adjacent metal.

### Example 16

The interconnect structure of example 15, wherein the adjacent metal is formed from same metal or metals as the upper metal.

### Example 17

The interconnect structure of any of examples 1-16, wherein the interconnect structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

### Example 18

A method of fabricating an interconnect structure, the method comprising: forming a lower line in a dielectric; and forming an upper line on or above the lower line, the upper line being electrically coupled with the lower line, the upper line comprising: an upper metal formed on or above the lower line; and an upper graphene formed on at least a portion of an upper surface of the upper metal, at least a portion of a first side surface of the upper metal, and/or at least a portion of a second side surface of the upper metal.

### Example 19

The method of example 18, wherein the upper metal comprises any one or more of Rhodium (Rh), Platinum (Pt), Iridium (Ir), Niobium (Nb), Nickel (Ni), Aluminium (Al), Ruthenium (Ru), Molybdenum (Mo), Osmium (Os), Copper (Cu), and Cobalt (Co).

### Example 20

The method of any of examples 18-19, further comprising: forming a via on or above the lower line, the via being electrically coupled with the upper line and with the lower line, the via comprising a via metal.

### Example 21

The method of example 20, wherein the via metal is formed from same metal or metals as the upper metal.

### Example 22

The method of any of examples 20-21, wherein the dielectric in which the lower line is formed is a first dielectric, wherein forming the upper line and forming the via comprises: etching a via pattern within an etch stop layer and a second dielectric layer, the etch stop layer being formed on the first dielectric and on the lower line, the second dielectric layer being formed on the etch stop layer, and the via pattern exposing at least a portion of an upper surface of the lower line; depositing a metal layer on or above the second dielectric layer and on or above the lower line, the metal layer filling the via pattern to form the via; etching the metal layer to form the upper metal; and forming the upper graphene on the first and second side surfaces and on the upper surface of the upper metal.

### Example 23

The method of example 22, wherein the upper graphene is formed on an entirety of the upper surface of the upper metal, an entirety of the first side surface of the upper metal, and/or an entirety of the second side surface of the upper metal.

### Example 24

The method of any of examples 22-23, wherein forming the upper line and forming the via further comprises: subsequent to etching the via pattern and prior to depositing the metal layer, depositing an adhesion layer on the second dielectric layer, on exposed portion of the etch stop layer, and on the exposed portion of the upper surface of the lower line, wherein the adhesion layer is also etched to form an upper adhesion layer when the metal layer is etched, and wherein the upper graphene is also formed on first and second side surfaces of the upper adhesion layer.

### Example 25

The method of any of examples 22-24, further comprising: forming an adjacent line comprising an adjacent metal and an adjacent graphene on at least a portion of an upper surface of the adjacent metal, at least a portion of a first side surface of the adjacent metal, and/or at least a portion of a second side surface of the adjacent metal, wherein the metal layer is etched to form the adjacent metal contemporaneously with the upper metal, and wherein the adjacent graphene is formed contemporaneously with the upper graphene.

### Example 26

The method of any of examples 20-21, wherein forming the upper line and forming the via comprises: depositing a first metal layer on or above the dielectric and on or above the lower line; depositing a second metal layer on or above the first metal layer; etching the first metal layer and the second metal layer to form the upper metal and to form the via metal above the upper metal; forming the upper graphene on the at least a portion of the upper surface of the upper metal, the at least a portion of the first side surface of the upper metal, and/or the at least a portion of the second side surface of the upper metal; and forming the via graphene on at least a portion of an upper surface of the via metal, at least a portion of a first side surface of the via metal, and/or at least a portion of a second side surface of the via metal.

### Example 27

The method of example 26, wherein the upper graphene wherein the upper graphene is formed on an entirety of the upper surface of the upper metal not covered by the via, an entirety of the first side surface of the upper metal, and/or an entirety of the second side surface of the upper metal, and/or wherein the via graphene is formed on an entirety of the upper surface of the via metal, an entirety of the first side surface of the via metal, and/or an entirety of the second side surface of the via metal.

### Example 28

The method of any of examples 26-27, wherein the upper graphene and the via graphene are formed from one graphene growth process.

### Example 29

The method of any of examples 26-28, wherein forming the upper line and forming the via further comprises: prior to depositing the first metal layer, depositing a first adhesion layer on the dielectric and on an upper surface of the lower line; subsequent to depositing the first metal layer and prior to depositing the second metal layer, depositing a second adhesion layer on an upper surface of the first metal layer, wherein the first adhesion layer and the second adhesion layer are also etched to respectively form an upper adhesion layer and a via adhesion layer when the first metal layer and the second metal layer are etched, and wherein the upper graphene is also formed on first and second side surfaces of the upper adhesion layer.

### Example 30

The method of any of examples 26-29, further comprising: forming an adjacent line comprising an adjacent metal and an adjacent graphene on at least a portion of an upper surface of the adjacent metal, at least a portion of a first side surface of the adjacent metal, and/or at least a portion of a second side surface of the adjacent metal, wherein the first metal layer is etched to form the adjacent metal contemporaneously with the upper metal, and wherein the adjacent graphene is formed contemporaneously with the upper graphene and the via graphene.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. An interconnect structure, comprising:
a lower line formed in a dielectric; and
an upper line formed on or above the lower line, the upper line being electrically coupled with the lower line, the upper line comprising:
an upper metal formed on or above the lower line; and
an upper graphene formed on at least a portion of an upper surface of the upper metal, at least a portion of a first side surface of the upper metal, and/or at least a portion of a second side surface of the upper metal.

2. The interconnect structure of claim 1, wherein the upper metal comprises any one or more of Rhodium (Rh), Platinum (Pt), Iridium (Ir), Niobium (Nb), Nickel (Ni), Aluminium (Al), Ruthenium (Ru), Molybdenum (Mo), Osmium (Os), Copper (Cu), and Cobalt (Co).

3. The interconnect structure of claim 1, wherein the upper line further comprises:
an upper adhesion layer formed on a lower surface of the upper metal.

4. The interconnect structure of claim 1, further comprising:
a via formed on or above the lower line, the via being electrically coupled with the upper line and with the lower line, the via comprising a via metal.

5. The interconnect structure of claim 4, wherein the via metal is formed from same metal or metals as the upper metal.

6. The interconnect structure of claim 4, wherein the via further comprises:
a via adhesion layer formed on a lower surface of the via metal.

7. The interconnect structure of claim 4, wherein the via is formed on an upper surface of the lower line and on a lower surface of the upper line such that the upper line is electrically coupled with the lower line through the via.

8. The interconnect structure of claim 7, wherein the via metal and the upper metal are integrally formed.

9. The interconnect structure of claim 7, wherein the upper graphene is formed on an entirety of the upper surface of the upper metal, an entirety of the first side surface of the upper metal, and/or an entirety of the second side surface of the upper metal.

10. The interconnect structure of claim 4, wherein the via is formed on an upper surface of the upper metal such that the via is electrically coupled with the lower line through the upper metal.

11. The interconnect structure of claim 10, wherein the upper graphene is formed on an entirety of the upper surface of the upper metal not covered by the via, an entirety of the first side surface of the upper metal, and/or an entirety of the second side surface of the upper metal.

12. The interconnect structure of claim 10, wherein the via further comprises a via graphene formed on at least a portion of an upper surface of the via metal, at least a portion of a first side surface of the via metal, and/or at least a portion of a second side surface of the via metal.

13. The interconnect structure of claim 12, wherein the via graphene is formed on an entirety of the upper surface of the via metal, an entirety of the first side surface of the via metal, and/or an entirety of the second side surface of the via metal.

14. The interconnect structure of claim 12, wherein the via graphene and the upper graphene are integrally formed.

15. The interconnect structure of claim 1, further comprising:
an adjacent line horizontally adjacent to the upper line, the adjacent line comprising:
an adjacent metal; and
an adjacent graphene formed on at least a portion of an upper surface of the adjacent metal, at least a portion of a first side surface of the adjacent metal, and/or at least a portion of a second side surface of the adjacent metal.

16. The interconnect structure of claim 15, wherein the adjacent metal is formed from same metal or metals as the upper metal.

17. The interconnect structure of claim 1, wherein the interconnect structure is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

18. A method of fabricating an interconnect structure, the method comprising:
forming a lower line in a dielectric; and
forming an upper line on or above the lower line, the upper line being electrically coupled with the lower line, the upper line comprising:
an upper metal formed on or above the lower line; and
an upper graphene formed on at least a portion of an upper surface of the upper metal, at least a portion of a first side surface of the upper metal, and/or at least a portion of a second side surface of the upper metal.

19. The method of claim 18, wherein the upper metal comprises any one or more of Rhodium (Rh), Platinum (Pt), Iridium (Ir), Niobium (Nb), Nickel (Ni), Aluminium (Al), Ruthenium (Ru), Molybdenum (Mo), Osmium (Os), Copper (Cu), and Cobalt (Co).

20. The method of claim 18, further comprising:
forming a via on or above the lower line, the via being electrically coupled with the upper line and with the lower line, the via comprising a via metal.

21. The method of claim 20, wherein the via metal is formed from same metal or metals as the upper metal.

22. The method of claim 20,
wherein the dielectric in which the lower line is formed is a first dielectric layer, and
wherein forming the upper line and forming the via comprises:
etching a via pattern within an etch stop layer and a second dielectric layer, the etch stop layer being formed on the first dielectric layer and on the lower line, the second dielectric layer being formed on the etch stop layer, and the via pattern exposing at least a portion of an upper surface of the lower line;
depositing a metal layer on or above the second dielectric layer and on or above the lower line, the metal layer filling the via pattern to form the via;
etching the metal layer to form the upper metal; and
forming the upper graphene on the first and second side surfaces and on the upper surface of the upper metal.

23. The method of claim 22, wherein the upper graphene is formed on an entirety of the upper surface of the upper metal, an entirety of the first side surface of the upper metal, and/or an entirety of the second side surface of the upper metal.

24. The method of claim 22, wherein forming the upper line and forming the via further comprises:
subsequent to etching the via pattern and prior to depositing the metal layer, depositing an adhesion layer on the second dielectric layer, on exposed portion of the etch stop layer, and on the exposed portion of the upper surface of the lower line,
wherein the adhesion layer is also etched to form an upper adhesion layer when the metal layer is etched, and
wherein the upper graphene is also formed on first and second side surfaces of the upper adhesion layer.

25. The method of claim 22, further comprising:
forming an adjacent line comprising an adjacent metal and an adjacent graphene on at least a portion of an upper surface of the adjacent metal, at least a portion of a first side surface of the adjacent metal, and/or at least a portion of a second side surface of the adjacent metal,
wherein the metal layer is etched to form the adjacent metal contemporaneously with the upper metal, and
wherein the adjacent graphene is formed contemporaneously with the upper graphene.

26. The method of claim 20, wherein forming the upper line and forming the via comprises:
depositing a first metal layer on or above the dielectric and on or above the lower line;
depositing a second metal layer on or above the first metal layer;
etching the first metal layer and the second metal layer to form the upper metal and to form the via metal above the upper metal;
forming the upper graphene on the at least a portion of the upper surface of the upper metal, the at least a portion of the first side surface of the upper metal, and/or the at least a portion of the second side surface of the upper metal; and
forming a via graphene on at least a portion of an upper surface of the via metal, at least a portion of a first side surface of the via metal, and/or at least a portion of a second side surface of the via metal.

27. The method of claim 26,
wherein the upper graphene is formed on an entirety of the upper surface of the upper metal not covered by the via, an entirety of the first side surface of the upper metal, and/or an entirety of the second side surface of the upper metal, and/or
wherein the via graphene is formed on an entirety of the upper surface of the via metal, an entirety of the first side surface of the via metal, and/or an entirety of the second side surface of the via metal.

28. The method of claim 26, wherein the upper graphene and the via graphene are formed from one graphene growth process.

29. The method of claim 26, wherein forming the upper line and forming the via further comprises:
prior to depositing the first metal layer, depositing a first adhesion layer on the dielectric and on an upper surface of the lower line; and
subsequent to depositing the first metal layer and prior to depositing the second metal layer, depositing a second adhesion layer on an upper surface of the first metal layer,
wherein the first adhesion layer and the second adhesion layer are also etched to respectively form an upper adhesion layer and a via adhesion layer when the first metal layer and the second metal layer are etched, and
wherein the upper graphene is also formed on first and second side surfaces of the upper adhesion layer.

30. The method of claim 26, further comprising:
forming an adjacent line comprising an adjacent metal and an adjacent graphene on at least a portion of an upper surface of the adjacent metal, at least a portion of a first side surface of the adjacent metal, and/or at least a portion of a second side surface of the adjacent metal,
wherein the first metal layer is etched to form the adjacent metal contemporaneously with the upper metal, and
wherein the adjacent graphene is formed contemporaneously with the upper graphene and the via graphene.
